(19) United States
(12) Patent Application Publication
(10) Pub. No.: US 2025/0262832 A1
(43) Pub. Date: Aug. 21, 2025

(54) SHAPING DEVICE

(71) Applicant: Murata Manufacturing Co., Ltd., Kyoto-fu (JP)

(72) Inventor: Toru KOMATSU, Nagaokakyo-shi (JP)

(21) Appl. No.: 19/197,331

(22) Filed: May 2, 2025

Related U.S. Application Data
(63) Continuation of application No. PCT/JP2023/037357, filed on Oct. 16, 2023.

(30) Foreign Application Priority Data
Nov. 7, 2022 (JP) 2022-178388

(51) Int. Cl. B30B 9/28; B30B 15/34

(52) U.S. Cl. CPC B30B 9/28; B30B 15/34

(57) ABSTRACT

A shaping device comprises: a base that can support a plate-shaped object; a plurality of support pins as a support member that can assume a first position to project upward from the base to support the object; a heating unit to heat the object while the object is supported by the plurality of support pins; and a biasing unit to bias the object downward, the plurality of support pins being movable upward and downward relative to the base.

### CROSS REFERENCE TO RELATED APPLICATION

This is a continuation of International Application No. PCT/JP2023/037357 filed on Oct. 16, 2023 which claims priority from Japanese Patent Application No. 2022-178388 filed on Nov. 7, 2022. The contents of these applications are incorporated herein by reference in their entireties.

### BACKGROUND OF THE DISCLOSURE

### Field of the Disclosure

The present disclosure relates to a shaping device.

### Description of the Related Art

In some cases, shaping a plate-shaped object is required as the object undergoes heat treatment or cooling treatment. A substrate processing apparatus for achieving such an object is described in Japanese Patent Laid-Open No. 2008-177303. The substrate processing apparatus comprises a heating plate. The heating plate has a surface with a plurality of pin-shaped projections formed thereon to form a gap having a predetermined dimension with a wafer. Furthermore, the heating plate has the surface with a ring-shaped partition wall disposed thereon to partition the gap in a radial direction. Such a structure is used to apply heat treatment to a distorted wafer.

### BRIEF SUMMARY OF THE DISCLOSURE

The substrate processing apparatus described in Japanese Patent Laid-Open No. 2008-177303 heats an object from below by the heating plate. The object is held by the plurality of pin-shaped projections. When the object is a soft object, such as a resin substrate, it is difficult to accurately shape the object into a planar shape while the object is held by the plurality of pin-shaped projections. Further, when the object is required to be shaped into a desired shape other than a planar shape, it is difficult to shape the object into a desired shape while the object is simply supported by the plurality of pin-shaped projections.

Accordingly, a possible benefit of the present disclosure is to provide a shaping device that can easily shape a plate-shaped object into a desired shape.

In order to achieve the above possible benefit, a shaping device according to the present disclosure comprises a base that can support a plate-shaped object, a support member that can assume a first position to project upward from the base to support the object, a heating unit to heat the object while the object is supported by the support member, and a biasing unit to bias the object downward. The support member is movable upward and downward relative to the base.

The present disclosure comprising a plurality of support pins movable upward and downward can facilitate shaping a plate-shaped object into a desired shape.

### BRIEF DESCRIPTION OF THE SEVERAL VIEWS OF THE DRAWINGS

FIG. 1 represents a concept of a shaping device according to a first embodiment based on the present disclosure.

FIG. 2 is a plan view of an object supporting unit that the shaping device according to the first embodiment based on the present disclosure comprises.

FIG. 3 is a cross section of the object supporting unit that the shaping device according to the first embodiment based on the present disclosure comprises for a first position.

FIG. 4 is a cross section of the object supporting unit that the shaping device according to the first embodiment based on the present disclosure comprises for a second position.

FIG. 5 illustrates a state in which an object is set in the object supporting unit of the shaping device according to the first embodiment based on the present disclosure.

FIG. 6 illustrates how the shaping device according to the first embodiment based on the present disclosure heats the object by a heating unit.

FIG. 7 illustrates a state in which the shaping device according to the first embodiment based on the present disclosure has a plurality of support pins moved downward.

FIG. 8 illustrates how the shaping device according to the first embodiment based on the present disclosure sucks the object through a suction port.

FIG. 9 illustrates how the shaping device according to the first embodiment based on the present disclosure lifts up the object after the shaping device completes cooling the object.

FIG. 10 is a first diagram for illustrating how the shaping device according to the first embodiment based on the present disclosure presses the object by a pressing member.

FIG. 11 is a second diagram for illustrating how the shaping device according to the first embodiment based on the present disclosure presses the object by the pressing member.

FIG. 12 is a cross section of an object supporting unit of a shaping device according to a second embodiment based on the present disclosure.

FIG. 13 illustrates a state in which an object is set in the object supporting unit of the shaping device according to the second embodiment based on the present disclosure.

FIG. 14 illustrates how the shaping device according to the second embodiment based on the present disclosure presses the object by the pressing member.

FIG. 15 is a cross section of an object supporting unit of a shaping device according to a third embodiment based on the present disclosure.

FIG. 16 illustrates a state in which an object is set in the object supporting unit of the shaping device according to the third embodiment based on the present disclosure.

FIG. 17 illustrates how the shaping device according to the third embodiment based on the present disclosure presses the object by the pressing member.

FIG. 18 illustrates an example of a shaping device according to the present disclosure comprising a pressing member that presses both a peripheral edge portion of an object and a middle portion of the object.

FIG. 19 is a cross section of an object supporting unit of a shaping device according to a fourth embodiment based on the present disclosure.

FIG. 20 is a cross section of an object supporting unit that a first modification of the shaping device according to the fourth embodiment based on the present disclosure comprises.

FIG. 21 is a cross section of an object supporting unit that a second modification of the shaping device according to the fourth embodiment based on the present disclosure comprises.

FIG. 22 is a cross section of an object supporting unit that a third modification of the shaping device according to the fourth embodiment based on the present disclosure comprises.

FIG. 23 is a cross section of an object supporting unit that a fourth modification of the shaping device according to the fourth embodiment based on the present disclosure comprises.

FIG. 24 is a cross section of an object supporting unit that a fifth modification of the shaping device according to the fourth embodiment based on the present disclosure comprises.

FIG. 25 is a cross section of an object supporting unit of a shaping device according to a fifth embodiment based on the present disclosure.

FIG. 26 is a cross section of an object supporting unit of a first modification of the shaping device according to the fifth embodiment based on the present disclosure.

FIG. 27 is a cross section of an object supporting unit of a second modification of the shaping device according to the fifth embodiment based on the present disclosure.

FIG. 28 is a cross section of an object supporting unit and a pressing member of a shaping device according to a sixth embodiment based on the present disclosure.

FIG. 29 is a cross section taken along a line XXIX-XXIX indicated in FIG. 28.

FIG. 30 is a cross section of a bar that a first modification of the shaping device according to the sixth embodiment based on the present disclosure comprises.

FIG. 31 is a cross section of a bar that a second modification of the shaping device according to the sixth embodiment based on the present disclosure comprises.

FIG. 32 is a cross section of a bar that a third modification of the shaping device according to the sixth embodiment based on the present disclosure comprises.

FIG. 33 is a cross section of a bar that a fourth modification of the shaping device according to the sixth embodiment based on the present disclosure comprises.

FIG. 34 is a cross section of an object supporting unit and a pressing member of a shaping device according to a seventh embodiment based on the present disclosure.

FIG. 35 is an enlarged view of a portion Z1 shown in FIG. 34.

FIG. 36 is a cross section taken along a line XXXVI-XXXVI indicated in FIG. 35.

FIG. 37 is a partially enlarged view of a bar that a first modification of the shaping device according to the seventh embodiment based on the present disclosure comprises.

FIG. 38 is a cross section taken along a line XXXVIII-XXXVIII indicated in FIG. 37.

FIG. 39 is a partially enlarged view of a bar that a second modification of the shaping device according to the seventh embodiment based on the present disclosure comprises.

FIG. 40 is a cross section taken along a line XL-XL indicated in FIG. 39.

FIG. 41 is a partially enlarged view of a bar that a third modification of the shaping device according to the seventh embodiment based on the present disclosure comprises.

FIG. 42 is a cross section taken along a line XLII-XLII indicated in FIG. 41.

FIG. 43 is a cross section of an object supporting unit and a pressing member of a shaping device according to an eighth embodiment based on the present disclosure.

FIG. 44 illustrates an operation of the object supporting unit of the shaping device according to the eighth embodiment based on the present disclosure.

FIG. 45 is a plan view of the object supporting unit of the shaping device according to the eighth embodiment based on the present disclosure.

FIG. 46 is a cross section of an object supporting unit and a pressing member of a shaping device according to a ninth embodiment based on the present disclosure.

FIG. 47 is a partial enlarged view of a portion Z2 shown in FIG. 46.

FIG. 48 is a partially enlarged view of the shaping device according to the ninth embodiment based on the present disclosure in use.

### DETAILED DESCRIPTION OF THE DISCLOSURE

Note that the figures do not necessarily faithfully represent a dimensional ratio as an actual dimensional ratio, and may instead exaggerate it for the sake of illustration. In the following description, when a reference is made to a concept of being upper or lower, it does not necessarily mean being absolutely upper or lower and may instead mean being relatively upper or lower with respect to a position illustrated in a figure.

A concept of “shaping” as referred to herein includes removing an undesired warpage of an object to make the object flat, or reducing the warpage. Further, the concept of “shaping” also includes intentionally deforming an object into a desired shape when the object does not have the desired shape.

### First Embodiment

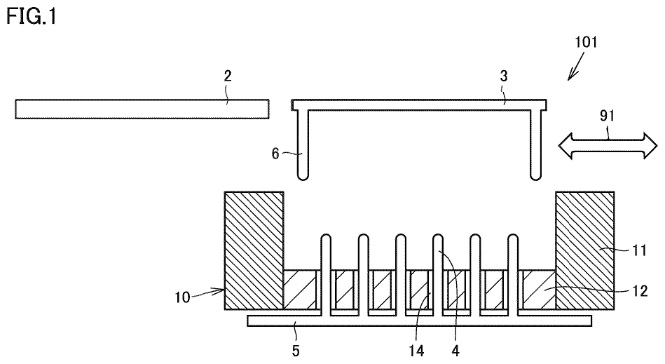

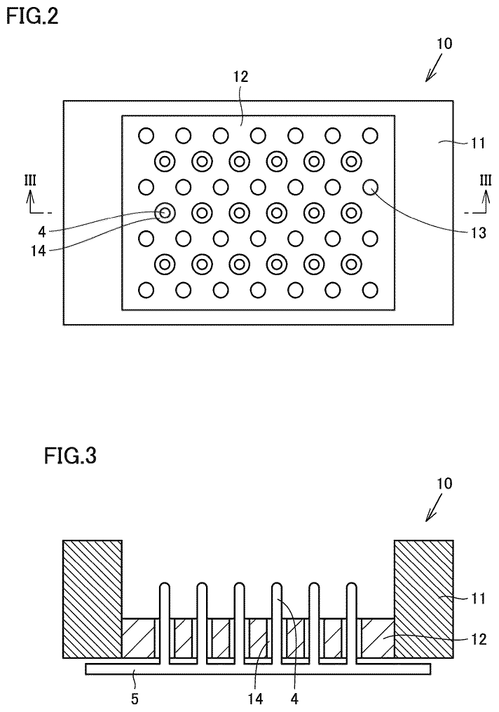

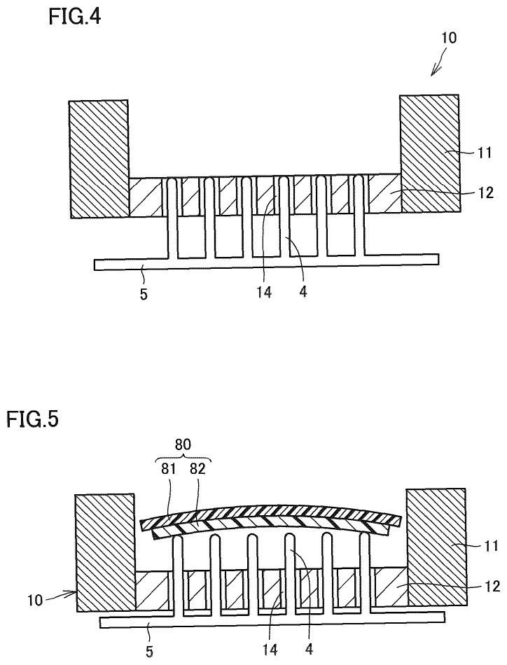

A shaping device according to a first embodiment based on the present disclosure will now be described with reference to FIGS. 1 to 5. FIG. 1 shows a shaping device 101 according to the present embodiment. Shaping device 101 comprises an object supporting unit 10, a heating unit 2, and a pressing member 3. Heating unit 2 and pressing member 3 may be movable laterally for example as indicated by an arrow 91. Heating unit 2 and pressing member 3 can move above object supporting unit 10, as necessary. FIG. 2 shows object supporting unit 10 as viewed from directly above. FIG. 3 is a cross section of object supporting unit 10 for a first position, and FIG. 4 is a cross section of the object supporting unit for a second position. FIG. 5 shows object 80 set in object supporting unit 10. In the example shown herein, object 80 includes a first resin layer 81 and a second resin layer 82. First resin layer 81 is a plate-shaped member formed of resin. Second resin layer 82 is disposed so as to cover a portion of one surface of first resin layer 81. The structure of object 80 indicated herein is merely an example, and it may be a different structure. Object 80 may have a configuration for example including a layer of a material other than resin, and may have a configuration composed of three or more layers deposited one on another. Object 80 may be any object insofar as it is a plate-shaped object.

Shaping device 101 comprises a base 12 that can support plate-shaped object 80, a support member that can assume a first position to project upward from base 12 to support object 80, heating unit 2 to heat object 80 while the object is supported by the support member, and a biasing unit to bias object 80 downward. The support member is movable upward and downward relative to base 12. A variety of structures can be considered for the structure of the support member. In the present embodiment, the support member includes a plurality of support pins 4. This is merely one example of the support member. The plurality of support pins 4 are movable upward and downward all together relative to base 12. Note that the plurality of support pins 4 as referred to herein may each have a tip having any shape insofar as it can support object 80 in contact with object 80, and are not limited to having the shape shown herein. The plurality of support pins 4 may each come into point contact with object 80. The plurality of support pins 4 are held together by a support pin holding unit 5. Object supporting unit 10 includes an outer periphery 11 and base 12. Base 12 is surrounded by outer periphery 11. Base 12 is provided with at least one suction port 13 and a plurality of through holes 14. The plurality of support pins 4 pass through the plurality of through holes 14, respectively. When the plurality of support pins 4 are moved upward, the first position is assumed as shown in FIG. 3, whereas when the plurality of support pins 4 are moved downward, the second position is assumed as shown in FIG. 4.

Heating unit 2 may emit halogen light, for example. Heating unit 2 may for example be an infrared heater. Heating unit 2 may blow warm air, for example. Heating unit 2 may heat in a method other than the method indicated herein by way of example.

Base 12 may include a cooling unit. That is, base 12 has a cooling function. Base 12 may have the cooling function implemented for example by circulating a fluid inside base 12. Base 12 may have the cooling function implemented for example by a Peltier element.

The biasing unit may be an instrument that presses object 80 downward from above, may be a suction device to suck object 80 from below, or may include both of them. Pressing member 3 is included in the biasing unit. Suction port 13 provided in base 12 is included in the biasing unit. While shaping device 101 comprises pressing member 3, it is not essential that the shaping device comprises pressing member 3.

An operation of the shaping device according to the present embodiment will now be described with reference to FIGS. 5 to 9. It should be noted, however, that what will be described hereafter is an operation of a shaping device that does not comprise pressing member 3.

Initially, as shown in FIG. 5, an object 80 is disposed in object supporting unit 10. At this point in time, object 80 is warped. Object 80 is supported by the plurality of support pins 4.

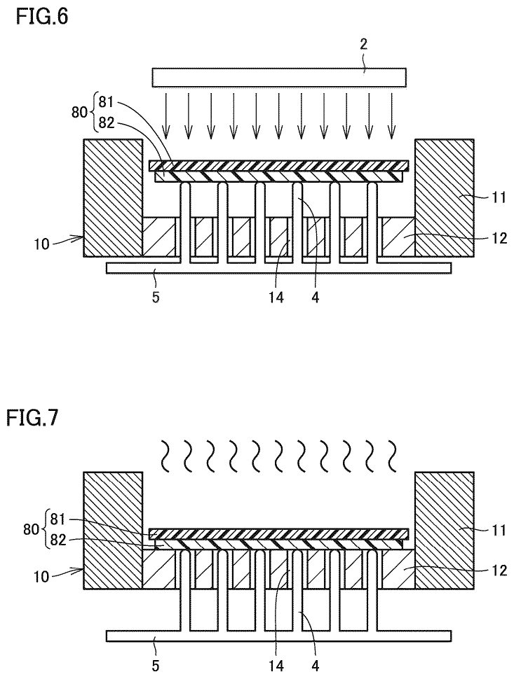

Subsequently, as illustrated in FIG. 6, heating unit 2 is used to heat object 80. As it is heated, object 80 is softened and thus less warped, and the object is thus supported by the plurality of support pins 4.

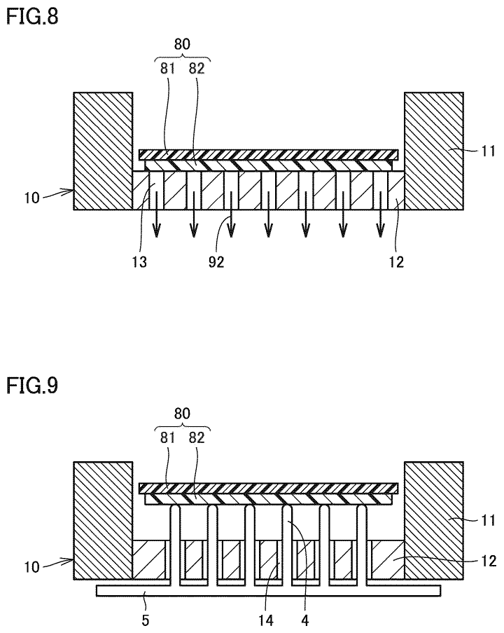

As shown in FIG. 7, the plurality of support pins 4 are moved downward. Moving support pin holding unit 5 downward allows the plurality of support pins 4 to be moved downward all together. At this point in time, the plurality of support pins 4 may have their upper ends in contact with object 80 or detached from object 80. In this state, as shown in FIG. 8, object 80 is sucked through suction port 13 in a direction indicated by an arrow 92. The cooling function of base 12 is used to cool object 80. When cooling the object is completed, the plurality of support pins 4 are moved upward as shown in FIG. 9. Object 80 is lifted upward away from base 12. At this point in time, object 80 has been shaped into a desired shape.

In the present embodiment, the plurality of support pins 4 can support object 80 and the plurality of support pins 4 are movable upward and downward relative to base 12, and when the object is heated the object can be supported by the plurality of support pins 80 whereas when the object is cooled the object can be supported by base 12, and the plate-shaped object is thus easily shaped into a desired shape.

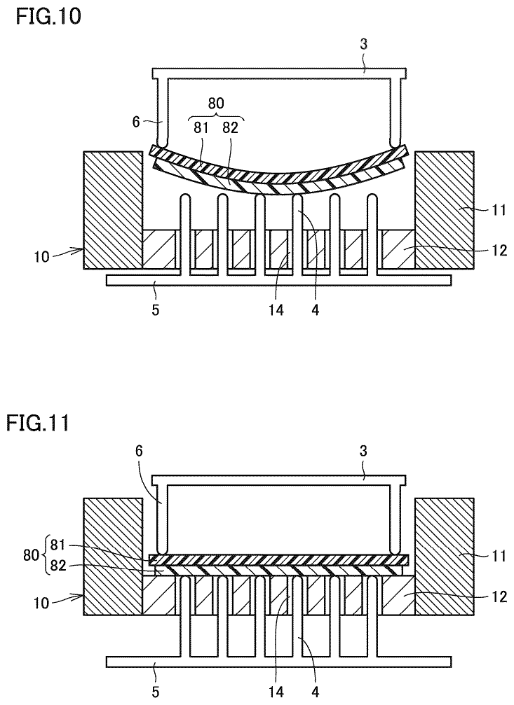

Note that it is preferable that the biasing unit include pressing member 3 including a projection 6 extending downward and having a tip to abut against object 80 to press object 80 downward. When the shaping device comprises the biasing unit including pressing member 3, then, for example as shown in FIG. 10, the shaping device can press a portion of a warped object 80 downward by pressing member 3. Pressing member 3 includes projection 6. In the example shown in FIG. 10, object 80 has a peripheral edge portion detached from the plurality of support pins 4 above, and pressing member 3 has projection 6 abutting against the peripheral edge portion of object 80. Object 80 having the peripheral edge portion pressed downward is deformed as shown in FIG. 11. Cooling the object in such a deformed state can more reliably shape the object into a desired shape.

As has been described in the present embodiment, the biasing unit may include a suction device to suck object 80 downward. This configuration allows object 80 to be sucked and thus held.

As has been described in the present embodiment, the plurality of support pins 4 can be moved from the first position downward to assume the second position, and it is preferable that base 12 be disposed such that for the first position object 80 is not in contact with base 12 and for the second position object 80 is in contact with base 12. This configuration allows object 80 to be held in contact with base 12 when it is unnecessary to lift object 80 by the plurality of support pins 4. A state of lifting and supporting object 80 by the plurality of support pins 4 and a state of disposing and supporting object 80 on base 12 can be easily switched by moving the plurality of support pins 4 upward and downward.

While in the present embodiment the plurality of support pins 4 are moved upward and downward all together, this is not exclusive. For example, the plurality of support pins 4 may be configured to be each capable of independently moving upward and downward.

As has been indicated in the present embodiment, the plurality of support pins 4 may have their upper ends flush with one another. This configuration allows object 80 to be heated while the plurality of support pins 4 are used to support object 80 flat.

While the first embodiment has been described based on an example with the plurality of support pins 4 having their upper ends flush with one another, a different configuration is also considered.

While the present embodiment has been described assuming that object 80 is a rectangle, object 80 is not limited in shape to a rectangle. Object 80 may have a square, polygonal, circular, elliptical, or any other shape.

### Second Embodiment

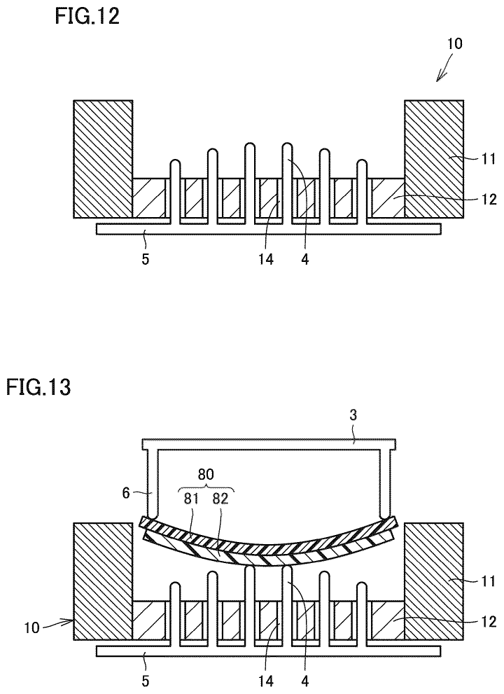

A shaping device according to a second embodiment based on the present disclosure will now be described with reference to FIGS. 12 to 14. For the second and subsequent embodiments, a part of the shaping device, or an object supporting unit, will be illustrated and described.

FIG. 12 shows object supporting unit 10 of the shaping device according to the present embodiment. In the present embodiment, when an imaginary plane connecting the upper ends of the plurality of support pins 4 is assumed, the imaginary plane is convex upward. In this example, an example with object 80 set is shown in FIG. 13. In this example, pressing member 3 is prepared for pressing a peripheral edge portion of object 80. By pressing the object downward using pressing member 3, a state as shown in FIG. 14 is achieved. The object can be heated or cooled while the object is thus pressed.

The present embodiment facilitates shaping a plate-shaped object into a desired shape.

### Third Embodiment

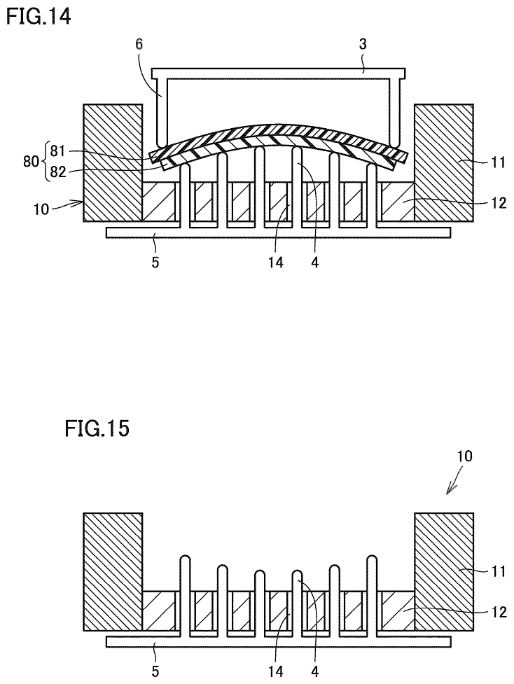

A shaping device according to a third embodiment based on the present disclosure will now be described with reference to FIGS. 15 to 17.

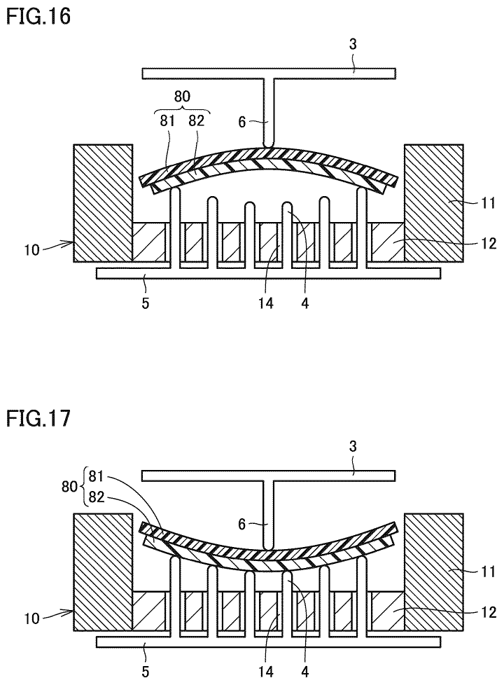

FIG. 15 shows object supporting unit 10 of the shaping device according to the present embodiment. In the present embodiment, when an imaginary plane connecting the upper ends of the plurality of support pins 4 is assumed, the imaginary plane is convex downward. In this example, an example with object 80 set is shown in FIG. 16. In this example, pressing member 3 is prepared for pressing a middle portion of object 80. By pressing the object downward using pressing member 3, a state is achieved as shown in FIG. 17. The object can be heated or cooled while the object is thus pressed.

The present embodiment facilitates shaping a plate-shaped object into a desired shape.

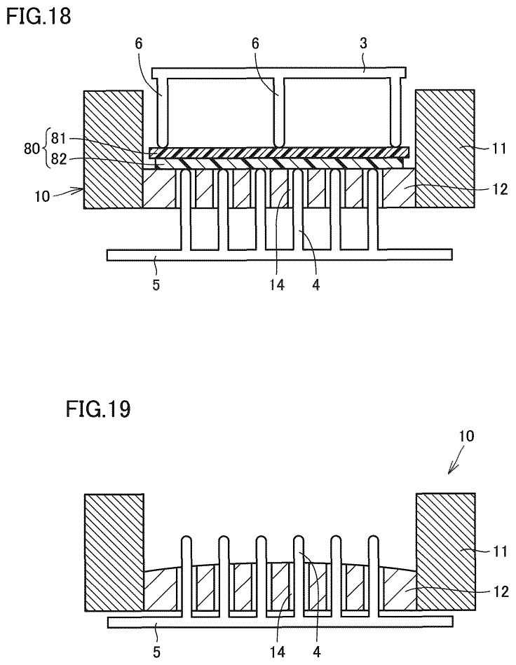

As shown in FIG. 18, pressing member 3 may press object 80 at both a peripheral edge portion and a middle portion.

Projection 6 of pressing member 3 is not limited in form to the examples shown in FIGS. 14, 17, 18, etc. Projection 6 is not necessarily fixed and may be any number of projections and may be repositionable. Projection 6 may be individually expandable and contractible in length. Projection 6 each repositionable or expandable and contractible in length may enable a configuration allowing a single pressing member 3 to be variously modified in form.

### Fourth Embodiment

A shaping device according to a fourth embodiment based on the present disclosure will now be described with reference to FIGS. 19 to 24.

FIG. 19 shows an example of object supporting unit 10 of the shaping device according to the present embodiment. Herein, base 12 has a convex upper surface. The plurality of support pins 4 have their upper ends flush with one another.

In the shaping device according to the present embodiment, base 12 has a convex or concave upper surface that comes into contact with object 80 for the second position.

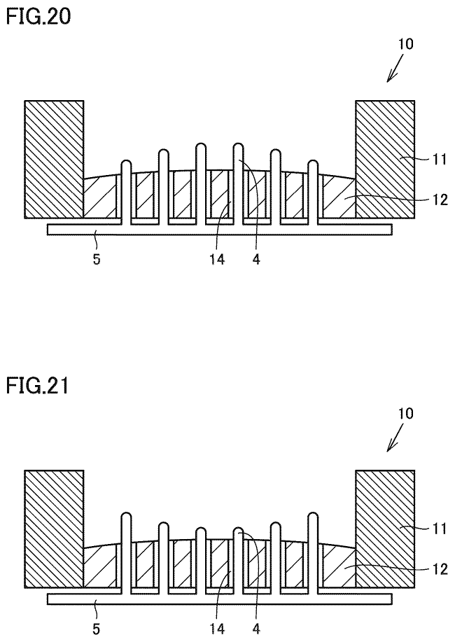

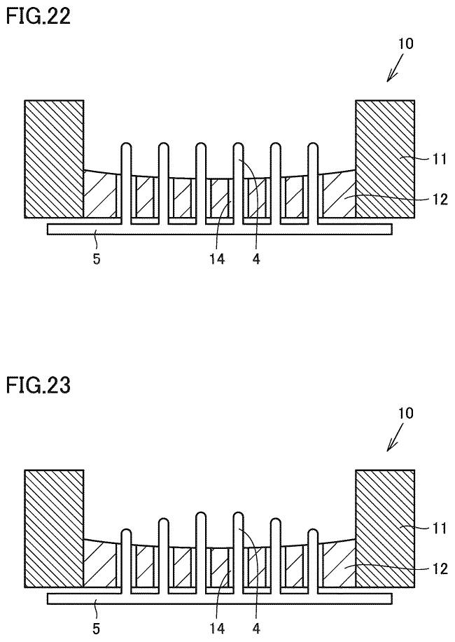

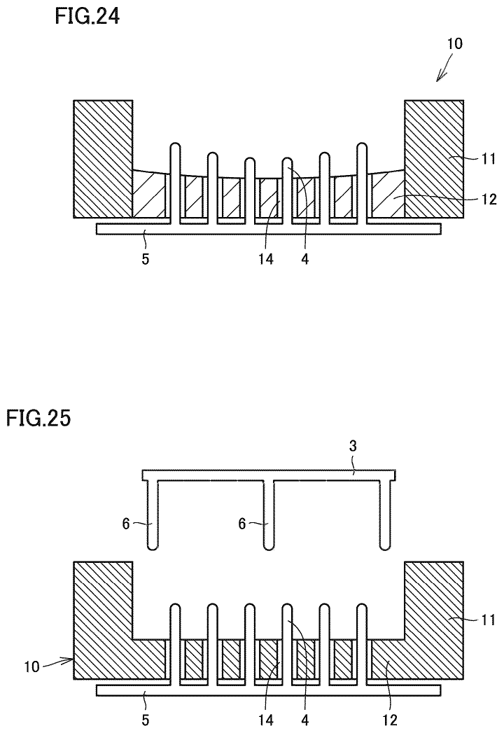

FIGS. 20 to 24 show modifications of the shaping device according to the present embodiment. In the example shown in FIG. 20, base 12 has a convex upper surface, and when an imaginary plane connecting the upper ends of the plurality of support pins 4 is assumed, the imaginary plane is convex upward. In the example shown in FIG. 21, base 12 has a convex upper surface, and when an imaginary plane connecting the upper ends of the plurality of support pins 4 is assumed, the imaginary plane is convex downward. In the example shown in FIG. 22, base 12 has a concave upper surface, and the plurality of support pins 4 have their upper ends flush with one another. In the example shown in FIG. 23, base 12 has a concave upper surface, and when an imaginary plane connecting the upper ends of the plurality of support pins 4 is assumed, the imaginary plane is convex upward. In the example shown in FIG. 24, base 12 has a concave upper surface, and when an imaginary plane connecting the upper ends of the plurality of support pins 4 is assumed, the imaginary plane is convex downward.

The present embodiment facilitates shaping a plate-shaped object into a desired shape. When it is desired to intentionally deflect the object in any direction and thus cool the object, it is convenient to convex or concave the upper surface of base 12 as indicated in the present embodiment.

### Fifth Embodiment

A shaping device according to a fifth embodiment based on the present disclosure will now be described with reference to FIGS. 25 to 27. FIG. 25 shows object supporting unit 10 and pressing member 3 of the shaping device according to the present embodiment. For this object supporting unit 10, pressing member 3 can press object 80 at both a peripheral edge portion and a middle portion. In the shaping device according to the present embodiment, base 12 does not include a cooling unit. Outer periphery 11 and base 12 are integrally formed of the same material. Thus, base 12 may be configured without including the cooling unit. The object may be cooled by a function of some device provided at a location other than base 12. Alternatively, the object may not be cooled by an actively cooling unit, and may instead be cooled by heat naturally radiated to the surroundings.

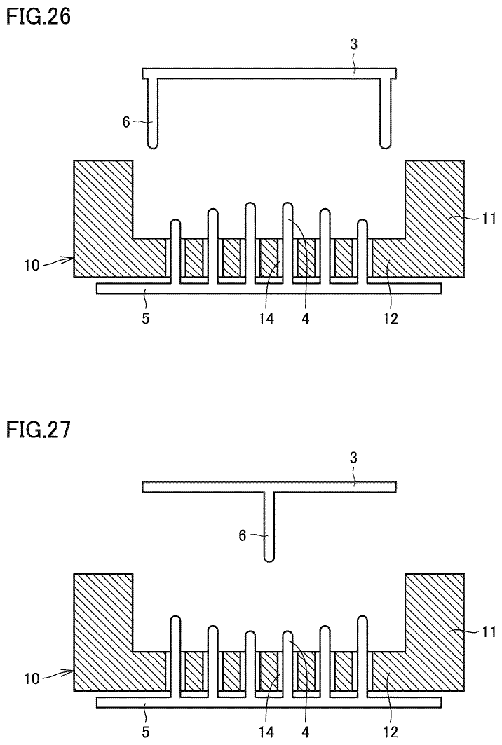

FIGS. 26 and 27 show modifications of the shaping device according to the present embodiment. The examples shown in FIGS. 26 and 27 differ from the example shown in FIG. 25 in how the plurality of support pins 4 and pressing member 3 are configured. Even when base 12 is configured without including the cooling unit, a variety of modifications are considered as illustrated in FIGS. 25 to 27.

The present embodiment facilitates shaping a plate-shaped object into a desired shape. In the present embodiment, object supporting unit 10 including base 12 can be simply structured.

### Sixth Embodiment

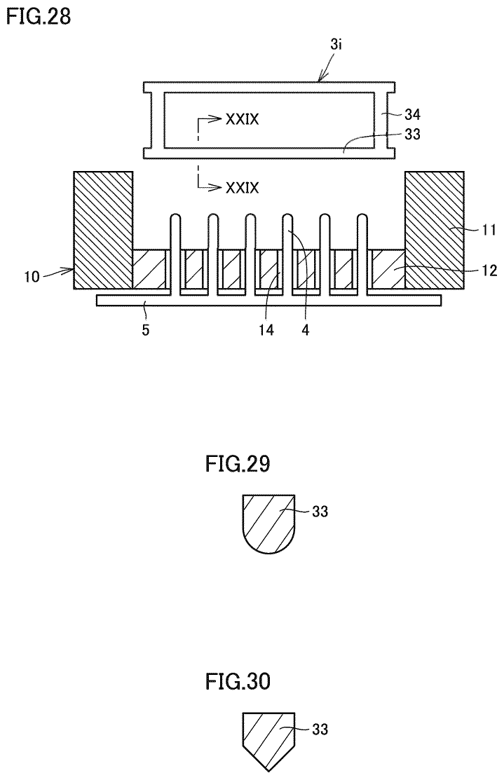

A shaping device according to a sixth embodiment based on the present disclosure will now be described with reference to FIGS. 28 and 29. FIG. 28 shows object supporting unit 10 and a pressing member 3i of the shaping device according to the present embodiment. In the shaping device according to the present embodiment, the biasing unit includes pressing member 3i including a bar 33 held in parallel to an upper surface of an object. Pressing member 3i can abut bar 33 against the object to press the object downward. Pressing member 3i includes two bar supports 34 and a single bar 33. Bar 33 is supported by two bar supports 34.

FIG. 29 is a cross section taken along a line XXIX-XXIX indicated in FIG. 28. Bar 33 in cross section has a shape of a combination of a rectangle and a semicircle. Bar 33 in cross section has a shape with a rounded lower side.

In the shaping device according to the present embodiment, the biasing unit's pressing member 3i can abut bar 33 against an object to bias the object downward, and thus more appropriately press the object. Bar 33 comes into contact with the object in a line.

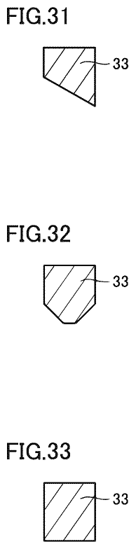

Note that the shape in cross section shown in FIG. 29 according to the present embodiment is merely one example. Instead of the shape shown in FIG. 29, bar 33 in cross section may have a shape with a lower side pointed as shown in FIGS. 30 and 31, for example. Alternatively, bar 33 in cross section may have a shape shown in FIGS. 32 and 33. FIG. 33 shows bar 33 in a rectangle in cross section. That is, bar 33 has a flat lower surface. When bar 33 in cross section has a shape shown in FIGS. 32 and 33, bar 33 will come into contact with an object in a plane.

### Seventh Embodiment

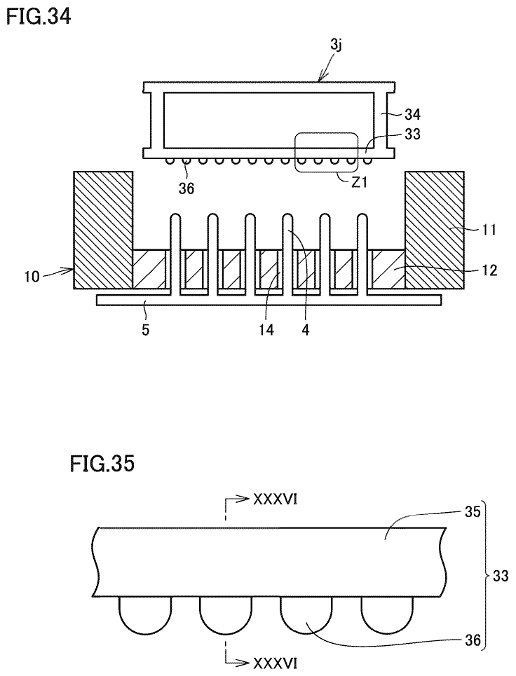

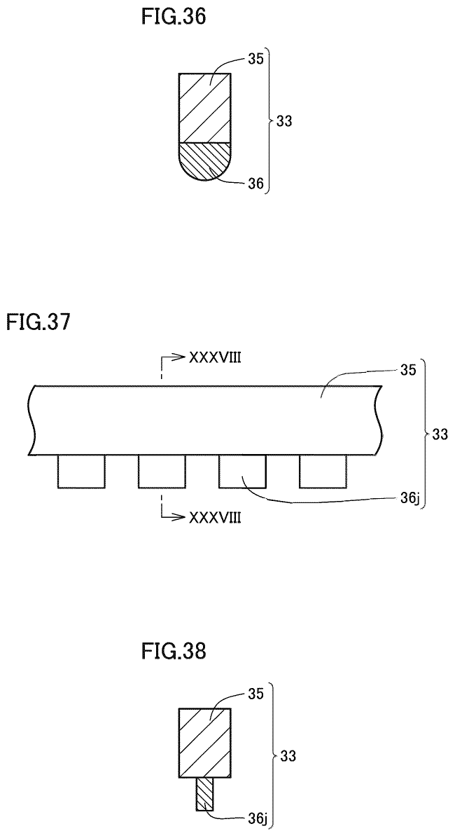

A shaping device according to a seventh embodiment based on the present disclosure will now be described with reference to FIGS. 34 to 36. FIG. 34 shows object supporting unit 10 and a pressing member 3j of the shaping device according to the present embodiment. In the shaping device according to the present embodiment, the biasing unit includes pressing member 3j including bar 33 held in parallel to an upper surface of an object. FIG. 35 is an enlarged view of a portion Z1 shown in FIG. 34. Although pressing member 3j is common in basic configuration to pressing member 3i, pressing member 3j includes bar 33 including a bar body 35 and one or more projections 36 disposed on a lower surface of bar body 35. In the example indicated herein, a plurality of projections 36 are disposed equidistantly on the lower surface of bar body 35. FIG. 36 is a cross section taken along a line XXXVI-XXXVI indicated in FIG. 35.

In the shaping device according to the present embodiment, the biasing unit's pressing member 3j can abut bar 33 against an object to bias the object downward, and when bar 33 abuts against the object, projections 36 abut against the object. That is, a point contact is made at a plurality of points. In the shaping device according to the present embodiment, the biasing unit can thus press an object more appropriately.

Note that the structure shown in FIGS. 35 and 36 according to the present embodiment is merely an example. The structure shown in FIG. 35 may be replaced with a structure shown in FIG. 37. FIG. 38 is a cross section taken along a line XXXVIII-XXXVIII indicated in FIG. 37. In this example, a plurality of projections 36j are disposed on a lower side of bar body 35. Projection 36j has a flat lower surface. As shown in FIG. 38, projection 36j is smaller in width than bar body 35.

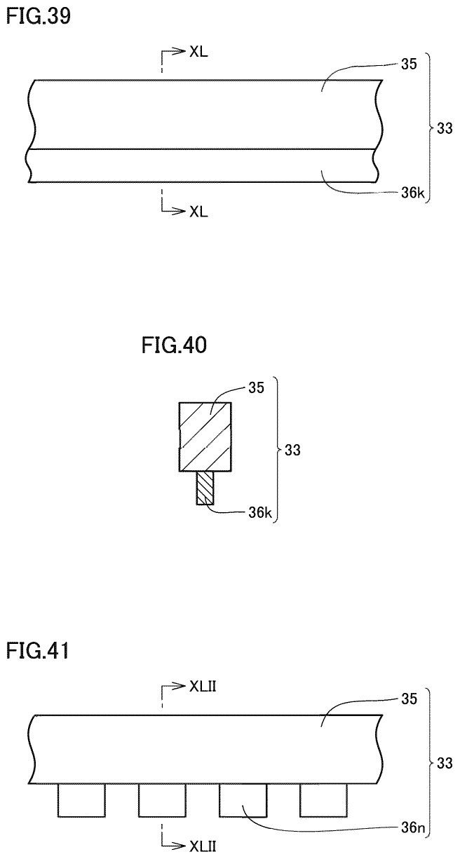

Bar 33 may be structured as shown in FIG. 39, for example. FIG. 40 is a cross section taken along a line XL-XL indicated in FIG. 39. In this example, a projection 36k that is one piece is disposed on the lower side of bar body 35. Bar 33 includes bar body 35 and projection 36k. Projection 36k has a flat lower surface. As shown in FIG. 40, projection 36k is smaller in width than bar body 35.

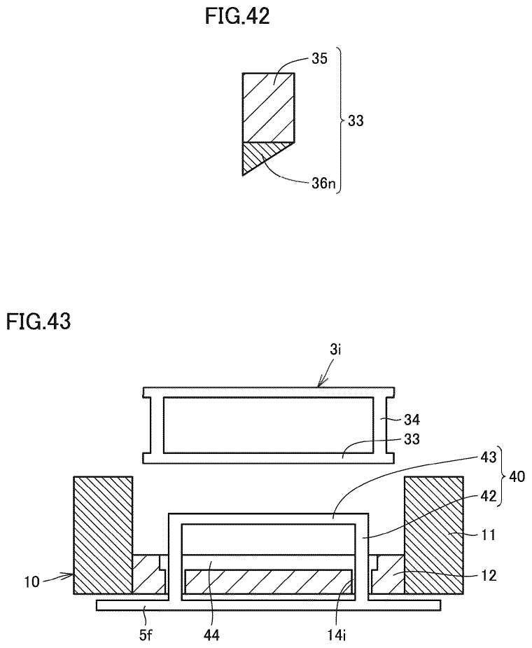

Bar 33 may be structured as shown in FIG. 41, for example. FIG. 42 is a cross section taken along a line XLII-XLII indicated in FIG. 41. In this example, a plurality of projections 36n are disposed on the lower side of bar 35. Each projection 36n in cross section has a triangular shape.

### Eighth Embodiment

A shaping device according to an eighth embodiment based on the present disclosure will now be described with reference to FIGS. 43 to 45. FIG. 43 shows object supporting unit 10 and pressing member 3i of the shaping device according to the present embodiment. In this shaping device, the biasing unit includes pressing member 3i including bar 33 held in parallel to an upper surface of an object. The shaping device comprises a support member 40. Support member 40 includes two or more columns 42 and a beam member 43 connecting upper ends of the two or more columns 42.

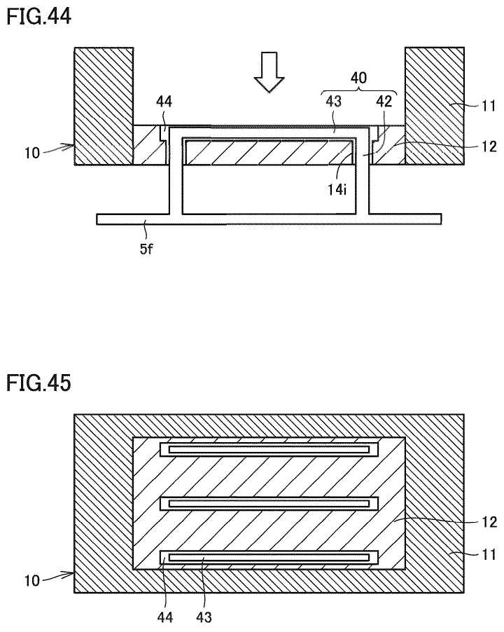

The shaping device may further have the following configuration. Base 12 has a beam member accommodating section 44 corresponding to beam member 43. In the second position, beam member 43 is accommodated in beam member accommodating section 44. FIG. 44 is a cross section of object supporting unit 10 while support member 40 assumes the second position. In the second position, column 42 is moved downward through a through hole 14i. In the second position, beam member 43 has an upper end equal to or lower than an uppermost surface of base 12 in level. FIG. 45 is a plan view of object supporting unit 10 for this position. In the example shown herein, base 12 has an upper surface provided with three linear beam member accommodating sections 44 in parallel. This is merely one example, and beam member 43 may be disposed in a positional relationship which is not parallel. Beam member 43 and beam member accommodating section 44 may not be three beam members and three beam member accommodating sections. In the example shown herein, bar 33 and beam member 43 are disposed in a position so that they overlap when viewed from directly above. Thus, three bars 33 are disposed in parallel when viewed from directly above. While a beam member 43 is visible in FIG. 43, the remaining two beam members 43 are located on a side behind this one beam member 43 with respect to the plane of the sheet of the figure.

The shaping device according to the present embodiment comprising support member 40 can support an object with beam member 43 and hence more appropriately.

### Ninth Embodiment

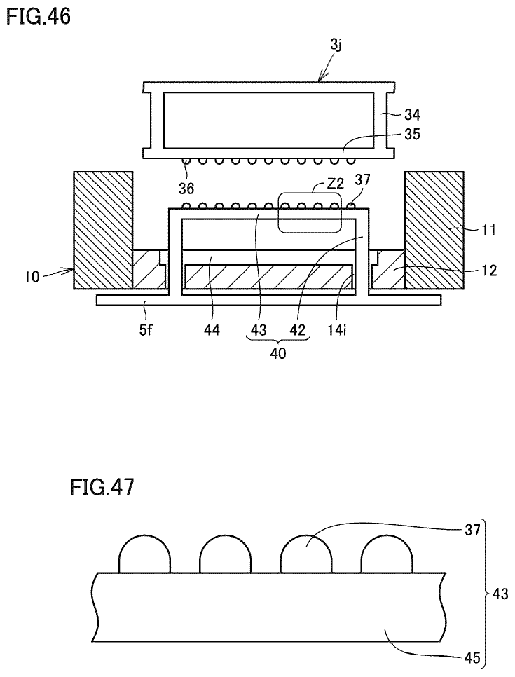

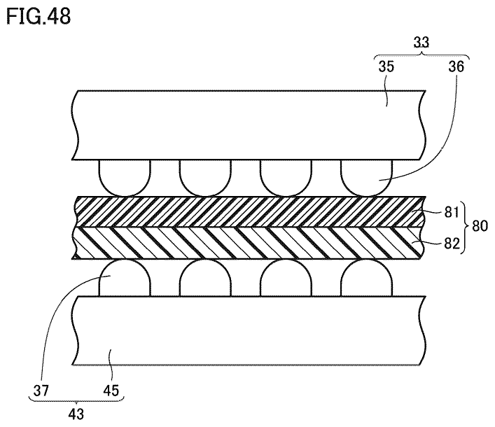

A shaping device according to a ninth embodiment based on the present disclosure will now be described with reference to FIGS. 46 and 47. FIG. 46 shows object supporting unit 10 and pressing member 3j of the shaping device according to the present embodiment. Pressing member 3j that this shaping device comprises is similar in configuration to pressing member 3j described in the seventh embodiment. FIG. 47 is an enlarged view of a portion Z2 shown in FIG. 46. Beam member 43 includes a body 45 of the beam member and a projection 37. The shape of projection 37 shown herein is merely an example. A variety of variations in structure of beam member 43 are considered. The variations in structure of beam member 43 are similar to those in structure of bar 33 shown in FIGS. 35 to 42, except that upper and lower sides are inverted. FIG. 48 is a partially enlarged view of a state in which object 80 is sandwiched between beam member 43 that is a part of support member 40 and bar 33 that is a part of pressing member 3j. A point at which projection 37 of beam member 43 abuts against object 80 and a point at which projection 36 of bar 33 abuts against object 80 correspond to each other, and are in a positional relationship in which they appear to overlap when viewed from directly above.

In the present embodiment, projection 37 of beam member 43 and projection 36 of bar 33 can sandwich and hold object 80 in point contact with object 80. This allows the object to be supported more appropriately.

Beam member 43 that is a part of support member 40 is not necessarily in a perfectly straight line. Beam member 43 may have a curved shape that is generally convex upward or convex downward. Such a configuration facilitates shaping a plate-shaped object into a desired shape.

Bar 33 that is a part of pressing member 3i or pressing member 3j is similarly

discussed. Bar 33 is not necessarily in a perfectly straight line. Bar 33 may have a curved shape that is generally convex upward or convex downward. Such a configuration facilitates shaping a plate-shaped object into a desired shape.

A plurality of the above-described embodiments may be combined, as appropriate, and employed. Note that the presently disclosed embodiments are illustrative and non-restrictive in any respect. The scope of the present disclosure is defined by the terms of the claims, and encompasses any modification falling within a meaning and scope equivalent to the claimed scope.

### Additional Notes

### Additional Note 1

A shaping device comprising: a base that can support a plate-shaped object; a plurality of support pins that can assume a first position to project upward from the base to support the object; a heating unit to heat the object while the object is supported by the plurality of support pins; and a biasing unit to bias the object downward, the plurality of support pins being movable upward and downward relative to the base.

### Additional Note 2

The shaping device according to Additional Note 1, wherein the biasing unit includes a pressing member including a projection extending downward and having a tip to abut against the object to press the object downward.

### Additional Note 3

The shaping device according to any one of Additional Notes 1 or 2, wherein the biasing unit includes a suction device to suck the object downward.

### Additional Note 4

The shaping device according to any one of Additional Notes 1 to 3, wherein the plurality of support pins can be moved from the first position downward to assume a second position, and the base is disposed such that for the first position the object does not come into contact with the base and for the second position the object comes into contact with the base.

### Additional Note 5

The shaping device according to Additional Note 4, wherein the base has a convex or concave upper surface that comes into contact with the object for the second position.

### Additional Note 6

The shaping device according to Additional Note 4 or 5, wherein the base includes a cooling unit.

### Additional Note 7

The shaping device according to any one of Additional Notes 1 to 6, wherein the plurality of support pins have upper ends flush with one another.

### Additional Note 8

The shaping device according to any one of Additional Notes 1 to 6, wherein when an imaginary plane connecting upper ends of the plurality of support pins is assumed, the imaginary plane is convex upward.

### Additional Note 9

The shaping device according to any one of Additional Notes 1 to 6, wherein when an imaginary plane connecting upper ends of the plurality of support pins is assumed, the imaginary plane is convex downward.

2 heating unit, 3, 3i, 3j pressing member, 4 support pin, 5 support pin holding unit, 5f holding unit, 6 projection, 10 object supporting unit, 11 outer periphery, 12 base, 13 suction port, 14,14i through hole, 33 bar, 34 bar support, 35 bar body, 36, 36j, 36k, 36n projection (provided on the bar), 37 projection (provided on a beam member), 40 support member, 42 column, 43 beam member, 44 beam member accommodating section, 45 body of beam member, 80 object, 81 first resin layer, 82 second resin layer, 91, 92 arrow, 101 shaping device.

1. A shaping device comprising:
a base configured to support a plate-shaped object;
a support member configured to take a first position to project upward from the base to support the object;
a heating unit configured to heat the object while the object is supported by the support member; and
a biasing unit configured to bias the object downward,
the support member being movable upward and downward relative to the base.

2. The shaping device according to claim 1, wherein the biasing unit includes a pressing member including a projection extending downward and having a tip to abut against the object to press the object downward.

3. The shaping device according to claim 1, wherein the biasing unit includes a pressing member including a bar held in parallel to an upper surface of the object, wherein the pressing member is configured to abut the bar against the object to press the object downward.

4. The shaping device according to claim 1, wherein the biasing unit includes a suction device to suck the object downward.

5. The shaping device according to claim 1, wherein
the support member is configured to take a second position moved downward from the first position, and
the base is disposed such that at the first position the object does not come into contact with the base and at the second position the object comes into contact with the base.

6. The shaping device according to claim 5, wherein the base has a convex or concave upper surface configured to come into contact with the object at the second position.

7. The shaping device according to claim 5, wherein the base includes a cooling unit.

8. The shaping device according to claim 1, wherein the support member includes a plurality of support pins.

9. The shaping device according to claim 8, wherein the plurality of support pins has upper ends flush with one another.

10. The shaping device according to claim 8, wherein when an imaginary plane connecting upper ends of the plurality of support pins is assumed, the imaginary plane is convex upward.

11. The shaping device according to claim 8, wherein when an imaginary plane connecting upper ends of the plurality of support pins is assumed, the imaginary plane is convex downward.

12. The shaping device according to claim 1, wherein the support member includes two or more columns and a beam member connecting upper ends of the two or more columns.

13. The shaping device according to claim 5, wherein the support member includes two or more columns and a beam member connecting upper ends of the two or more columns, the base includes a beam member accommodating section corresponding to the beam member, and at the second position the beam member is accommodated in the beam member accommodating section.

14. The shaping device according to claim 2, wherein the biasing unit includes a suction device to suck the object downward.

15. The shaping device according to claim 3, wherein the biasing unit includes a suction device to suck the object downward.

16. The shaping device according to claim 2, wherein
the support member is configured to take a second position moved downward from the first position, and
the base is disposed such that at the first position the object does not come into contact with the base and at the second position the object comes into contact with the base.

17. The shaping device according to claim 3, wherein
the support member is configured to take a second position moved downward from the first position, and
the base is disposed such that at the first position the object does not come into contact with the base and at the second position the object comes into contact with the base.

18. The shaping device according to claim 4, wherein
the support member is configured to take a second position moved downward from the first position, and
the base is disposed such that at the first position the object does not come into contact with the base and at the second position the object comes into contact with the base.

19. The shaping device according to claim 6, wherein the base includes a cooling unit.

20. The shaping device according to claim 2, wherein the support member includes a plurality of support pins.
